(19) United States
(12) Patent Application Publication
(10) Pub. No.: US 2002/0094593 A1
(43) Pub. Date: Jul. 18, 2002

(54) Method for adjusting optical properties of an anti-reflective coating layer

(75) Inventors: Wen-Chih Chiou, Miaoli (TW); Syun-Ming Jang, Hsin-Chu (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 09/761,486

(22) Filed: Jan. 16, 2001

(51) Int. Cl. H01L 21/00

(52) U.S. Cl. 438/29

(57) ABSTRACT

A method for adjusting the optical properties of an anti-reflective coating layer by thermal annealing is described. In the method, a dielectric ARC layer of SiON is first deposited by plasma enhanced CVD to a thickness of at least 500 Å. The dielectric ARC layer is deposited on a silicon nitride layer or on a polysilicon layer which can withstand the annealing temperature used for the dielectric ARC layer. The dielectric ARC layer can be annealed at a temperature of at least 400° C., or in a temperature range between about 400° C. and about 1,000° C. The annealing process can be conducted in a gas environment that contains at least one of N₂and O₂. A suitable annealing time is between about 1 min. and about 30 min., or preferably between about 3 min. and about 5 min. The annealing process has substantially no effect on the value of the reflective index, n, the present invention novel method allows adjustment in the extinction coefficient, k, to be made independently in the SiON dielectric ARC layer.

### FIELD OF THE INVENTION

The present invention generally relates to a method for adjusting the optical properties of an anti-reflective coating (ARC) layer and more particularly, relates to a method for adjusting an extinction coefficient of a dielectric, anti-reflective coating layer by annealing at a temperature of at least 400° C. in a gas environment that includes at least one of O₂ and N₂.

### BACKGROUND OF THE INVENTION

Anti-reflective coatings are frequently used in semiconductor processing to reduce light reflectance on the surface of metallic layers. Conventionally, the coatings are used on aluminum metallization layers which are deposited on wafer as interconnects. Aluminum is a widely used material for metallization layer in semiconductor processing, based on its desirable properties of low melting point, high conductivity and low cost. However, one drawback of aluminum is that the surface of the metal is highly reflective. The high surface reflectively greatly impedes the imaging process necessary for lithography. In a lithographic process, a photoresist layer must be deposited on the aluminum surface and then photographically patterned based on a pattern previously formed in a photo-imaging mask. The high reflectivity from the surface of aluminum renders this photographic transfer process extremely difficult.

To reduce the high reflectivity of aluminum, an anti-reflective coating layer of a refractory metal nitride can be deposited on the surface of aluminum. Typical refractory metal nitrides used are titanium nitride and tungsten nitride. A titanium nitride layer appears as a brown or golden tint which significantly reduces the reflectivity of aluminum from a near 100% to approximately 20% at the wavelengths of visible light. The anti-reflective coating deposition process is important in semiconductor processing whenever a highly reflective metal layer is used.

In a deposition process for an anti-reflective coating (ARC) on an aluminum layer, a typical stack of a metal contact layer and a refractory metal nitride layer is formed for reducing optical reflections. For instance, a titanium nitride (TiN) layer is frequently used as the final layer or the anti-reflective coating on aluminum metallization structures. A thin layer, i.e. generally in the range between about 150 Å and about 500 Å, reduces the reflective properties of the underlying aluminum to enable an optimum feature size control in a photolithographic process. In the conventional method, a TiN layer can be fabricated by first depositing Ti immediately following an Al deposition process in a cluster deposition tool and then rapid thermal nitridation. The TiN layer can also be formed by a reactive sputtering technique.

In modern semiconductor devices, polysilicon and silicon nitride have been commonly used as conductive layers and insulating layers, respectively. These layers frequently must be patterned and formed by a standard photolithographic process. The surface of a polysilicon layer or a silicon nitride layer is also highly reflective, almost matching that of an aluminum layer. The high reflectivity of the surface of polysilicon or silicon nitride renders an imaging process for lithography difficult to carry out. The use of an anti-reflective coating layer on top of the polysilicon or the silicon nitride prior to depositing a photoresist layer is therefore necessary. For compatibility reasons, a dielectric type anti-reflective coating material is more suitable for coating the polysilicon or the silicon nitride surface. The dielectric ARC, which is quite different than organic ARC such as organic dyes or inorganic ARC such as TiN or TiW, may be SiO₂, SiON or SiONH. The dielectric ARC is deposited as a bottom ARC, i.e. directly on a wafer under a photoresist layer by a plasma CVD method. Reactant gases such as SiH₄+O₂+N₂ or SiH₄+N₂O or SiH₄+N₂O+N₂ may be used to produce the suitable dielectric ARC layer on a wafer surface.

Two important optical properties for a dielectric ARC layer are the reflective index, n; and the extinction coefficient, k. The values of n and k are dependent upon the thickness of the coating layer deposited. The reflective index n is a ratio of c/v, where c is the light velocity in vacuum, and v is the light velocity in the material of interest. The extinction coefficient k is also a function of the wave length of optical beams.

In selecting a suitable thickness and material for the dielectric ARC, it has been found that suitable values of n and k of the dielectric ARC layer must be maintained. Since the photolithographic process is sensitive to the values of n and k, the values of the two parameters must be accurately controlled by adjusting the plasma CVD recipe, as conventionally performed. However, there is a fixed relationship between the values of n and k, and thus any adjustment for the two values cannot be controlled independently. For instance, the conventional method of controlling n and k by adjusting the plasma CVD recipe cannot be used if only one value, such as k, needs to be adjusted. As a result, the photolithographic requirement for a specific combination of n and k values frequently cannot be met.

### SUMMARY OF THE INVENTION

It is therefore an object of the present invention to provide a method for adjusting the optical properties of an anti-reflective coating layer without the drawbacks or shortcomings of the conventional methods.

It is another object of the present invention to provide a method for adjusting the optical properties of an anti-reflective coating layer without adjusting the plasma CVD recipe used for depositing the coating layer.

It is a further object of the present invention to provide a method for adjusting the optical properties of an anti-reflective coating layer on top of a silicon nitride or a polysilicon layer on a semiconductor substrate.

It is another further object of the present invention to provide a method for adjusting the optical properties of an anti-reflective coating layer by depositing a dielectric ARC layer on silicon nitride or polysilicon on top of a semiconductor substrate.

It is still another object of the present invention to provide a method for adjusting the optical properties of an anti-reflective coating layer by annealing a dielectric ARC layer deposited on silicon nitride or polysilicon at a temperature of at least 400° C. in a gas environment containing at least one of N₂ and O₂.

It is yet another object of the present invention to provide a method for adjusting the optical properties of a dielectric anti-reflective coating layer that has a thickness of at least 500 Å by annealing the layer at a temperature of at least 600° C. in a gas environment of N₂, O₂ or N₂/O₂.

It is still another further object of the present invention to provide a method for adjusting the extinction coefficient of a dielectric anti-reflective coating layer that is deposited on a silicon nitride layer or a polysilicon layer on a semiconductor substrate.

It is yet another further object of the present invention to provide a method for adjusting the extinction coefficient of a dielectric anti-reflective coating layer of SiO₂, SiON or SiONH on top of a silicon nitride or a polysilicon layer on a semiconductor substrate by annealing the dielectric ARC layer at a temperature of at least 400° C. in an environment of N₂, O₂ or N₂/O₂.

In accordance with the present invention, a method for adjusting the optical properties of an anti-reflective coating layer formed of a dielectric material is provided.

In a preferred embodiment, the method for adjusting the optical properties of an anti-reflective coating layer can be carried out by first providing a preprocessed semiconductor substrate that has a silicon nitride or a polysilicon layer deposited on top, then depositing a dielectric ARC layer on the silicon nitride or polysilicon layer, then annealing the dielectric ARC layer deposited on the semiconductor substrate at a temperature of at least 400° C. and in a gas environment including at least one of N₂ and O₂.

The method for adjusting the optical properties of an anti-reflective coating layer may further include the step of depositing SiON or SiONH on the silicon nitride or the polysilicon layer.

The method may further include the step of depositing SiON on the silicon nitride or the polysilicon layer by a plasma enhanced chemical vapor deposition technique, or by a plasma enhanced chemical vapor deposition technique to a thickness of at least 500 Å. The gas utilized for the annealing process can be O₂, N₂ or a mixture of O₂/N₂.

In the method for adjusting the optical properties of a dielectric ARC layer, the dielectric anti-reflective coating layer is deposited of a material selected from the group consisting of SiO₂, SiON and SiONH. The method may further include the step of annealing the dielectric ARC layer at a temperature between about 400° C. and about 1,000° C. The method may further include the step of annealing the dielectric ARC layer for a timer period between about 1 min. and about 30 min., preferably between about 3 min. and about 5 min. The method may further include the step of adjusting the optical properties of the dielectric ARC layer to a reflective index (n) between about 2.0 and about 2.5, and an extinction coefficient (k) between about 0.2 and about 0.8.

The present invention is further directed to a method for adjusting the extinction coefficient (k) of a dielectric ARC layer by the steps of first providing a silicon nitride layer or a polysilicon layer covered semiconductor substrate, depositing a dielectric ARC layer selected from the group consisting of SiO₂, SiON and SiONH on the silicon nitride or on the polysilicon layer, and heating the semiconductor substrate to a temperature between about 400° C. and about 1,000° C. in an environment that includes at least one of N₂ or O₂.

The method for adjusting the extinction coefficient of a dielectric ARC layer may further include the step of heating the semiconductor substrate for a length of time sufficient to vary the extinction coefficient of the dielectric ARC layer, or the step of heating the semiconductor substrate for a length of time between about 1 min. and about 30 min., or preferably between about 3 min. and about 5 min. The method may further include the step of heating the semiconductor substrate to a temperature of about 600° C. in an environment of O₂.

### BRIEF DESCRIPTION OF THE DRAWINGS

These and other objects, features and advantages of the present invention will become apparent from the following detailed description and the appended drawings in which:

FIG. 1 is a graph illustrating changes in the reflective index based on changes in the SiH₄/N₂O mix ratio for a dielectric ARC layer of SiON.

FIG. 2 is a graph illustrating changes in the extinction coefficient based on changes in the SiH₄/N₂O mix ratio for a dielectric ARC of SiON.

FIG. 3 is a graph illustrating a relationship between the reflective index and the extinction coefficient for a dielectric ARC of SiON.

FIG. 4 is a graph illustrating the effect of annealing on the reflective index n and the extinction coefficient k at various annealing temperatures between 300° C. and 900° C.

FIG. 5 is a graph illustrating the relationship between the reflective index n and the extinction coefficient k as deposited and after annealing in O₂ for a dielectric ARC of SiON.

### DETAILED DESCRIPTION OF THE PREFERRED EMBODIMENT

The present invention discloses a method for adjusting the optical properties of an anti-reflective coating layer or a dielectric ARC layer. The present invention method is particularly suited for adjusting the extinction coefficient, k, of a dielectric ARC layer while holding the reflective index, n, at a constant value. The present invention novel method is particularly useful when a specific photolithographic process requires a different set of n and k values which requires changes to be made in one value but not in the other value. The conventional method of adjusting the values of the parameters is to change the plasma CVD recipe resulting in changes in both parameters. By utilizing the present invention novel method, the value of one parameter can be held constant while the value of the other parameter is being changed. For instance, the value of the reflective index n for a dielectric ARC layer of SiON can be held constant, while the extinction coefficient k of SiON can be reduced by a suitable annealing process. The present invention novel method enables the adjustment of a single optical parameter independently of the other optical parameter.

In the present invention novel method, thermal annealing of the as-deposited dielectric ARC layer is carried out in O₂, N₂ or a mixture of N₂/O₂ in a furnace or in a RTA (rapid thermal anneal) chamber capable of heating a substrate up to 1,000° C. The method may produce any n and k value combinations for a lithographic process. The method further enables a photoresist footing reduction which improves the resolution of a photolithographic process.

The present invention method thermally anneals an as-deposited dielectric ARC layer of SiON to reduce the extinction coefficient k effectively, while keeping the reflective index n constant. It enables the adjustment of k value only by an annealing process which can be advantageously carried out in a furnace or in a rapid thermal annealing chamber, depending on the thermal budget requirement. The annealing temperature should be higher than 400° C., or in the range between about 400° C. and about 1,000° C. The word “about” used in this specification indicates a range of ±10% from the average value given.

At higher annealing temperatures, a lower k value of the dielectric ARC layer of SiON is achieved. It is also discovered that the O₂ atmosphere is more effective than N₂. Another advantage made possible by the present invention method is that O₂ annealing can reduce photoresist footing effectively by Si—N bond reduction. It is believed that when the dielectric ARC layer of SiON is annealed in O₂, the Si—N bond in a surface layer decreases, while the Si—O bond increases. The reaction between the dielectric ARC layer and the photoresist layer is therefore decreased. This is important, especially when deep UV photoresist material is utilized which is sensitive to Si—N bond and which can produce the footing effect, thus sacrificing the resolution of the lithographic process. By practicing the present invention method in an O₂ environment, the footing effect is greatly reduced resulting in an improvement in the definition of the pattern. Since the photolithographic process requires optimized n and k values, the present invention novel method of annealing improves bonding in SiON, i.e. the annealing process changes unstable bonding to stable bonding, leading to smaller extinction coefficient, or k values.

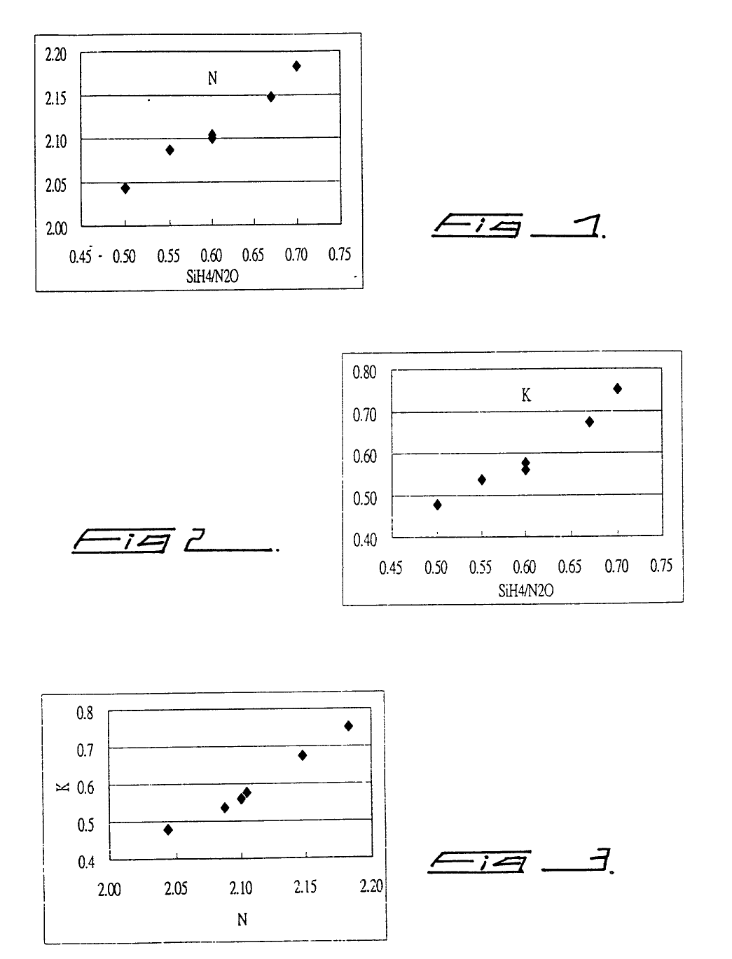

Referring now to FIG. 1 which is a graph illustrating the changes in n, the reflective index based on changes in the SiH₄/N₂O mix ratio. It is seen that the higher the mix ratio, i.e. the more SiH₄ contained in the mixture, the higher the reflective index is obtained. Similarly, FIG. 2 is a graph illustrating changes in the k value, the extinction coefficient value based on changes in the SiH₄/N₂O mix ratio. A similar dependency is seen in that higher k values are obtained at higher percentages of SiH₄ in the reactant gas mixture for forming the SiON layer.

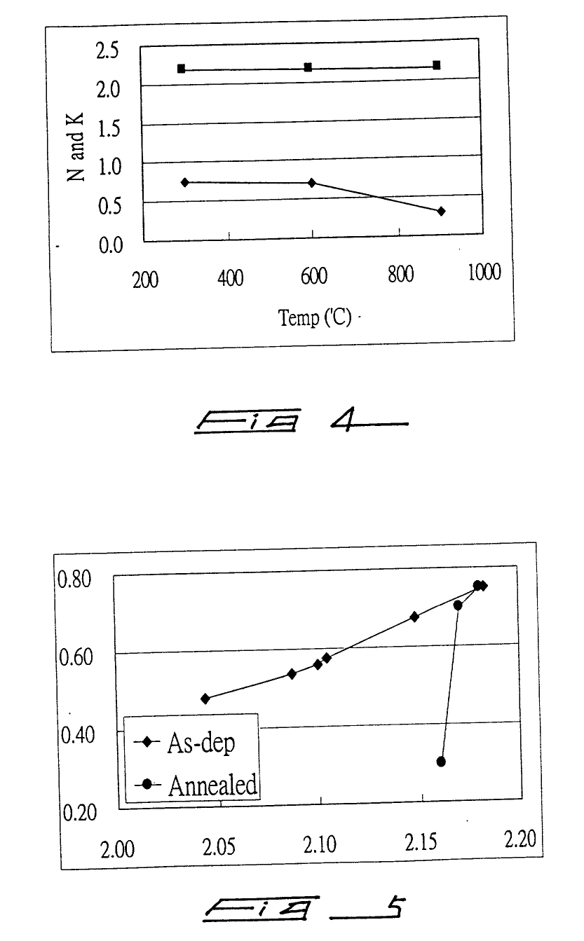

A plasma enhanced CVD process for depositing a SiON layer at 400° C. to a thickness of approximately 620 Å is used to produce data shown in FIGS. 1 and 2. The inter-dependency between the two parameters of k and n is shown in FIG. 3. It is seen that a linear relationship exists in-between the two parameters.

Data obtained by utilizing the present invention novel method for thermal annealing a dielectric ARC layer for achieving independent control of the optical parameters is shown in FIGS. 4 and 5.

FIG. 4 shows data of n and k obtained after a semiconductor substrate that has a SiON layer deposited on top is annealed at various temperatures between 300° C. and 900° C. Specifically, three annealing temperatures were utilized, i.e. 300° C., 600° and 900° C. It is shown that the present invention method can be advantageously used to control a single parameter of k, i.e. the extinction coefficient by annealing the structure at various temperatures, while the reflective index n remains substantially unchanged after various annealing processes. The annealing processes shown in FIGS. 4 and 5 are conducted in an oxygen environment, in order to achieve the additional benefit of having reduced footing effect. The annealing time utilized is normally about 3 min., or in the range between about 1 min. and about 30 min., preferably between about 3 min. and about 5 min.

It is important to note, in FIG. 4, that the present invention novel method is made possible by the fact that, at least for the dielectric ARC layer of SiON, the reflective index n remains substantially unchanged after annealing at various annealing temperatures, while the value of the extinction coefficient, k, decreases with increasing annealing temperatures.

The beneficial effect of the present invention novel method is further illustrated in FIG. 5, i.e. in a graph illustrating the inter-dependency of the extinction coefficient k on the reflective index n. It is seen that, while the as-deposited SiON layer shows a linear dependency between the two parameters, the annealed films show an entirely different result. After annealing in an oxygen environment for a time period of about 3 min., the reflective index value, n, remains substantially unchanged (fluctuating between a value of 2.16 and 2.18), while the value of the extinction coefficient, k, changes drastically from 0.70 to about 0.30. A film thickness for the SiON layer deposited by the plasma enhanced CVD method is about 620 Å. It should be noted that, for comparison purposes, n=1.46 and k=0 for a pure SiO₂ layer, while n=2˜2.1 and k=0.3 for a pure Si₃N₄ layer.

It was determined that suitable values for the dielectric ARC layer of SiON, having a thickness of about 620 Å, are the reflective index n=2.0˜2.5, the extinction coefficient k=0.2˜0.8. By utilizing the present invention novel method, an annealing process for changing the k value can be advantageously carried out at an annealing temperature between about 400° C. and about 1,000° C. The annealing time may be between about 1 min. and about 30 min., or preferably between about 3 min. and about 5 min.

The present invention novel method for adjusting optical properties, i.e. the reflective index and the extinction coefficient, of a dielectric anti-reflective coating layer has therefore been amply described in the above description and in the appended drawings of FIGS. 1˜5.

While the present invention has been described in an illustrative manner, it should be understood that the terminology used is intended to be in a nature of words of description rather than of limitation.

Furthermore, while the present invention has been described in terms of a preferred embodiment, it is to be appreciated that those skilled in the art will readily apply these teachings to other possible variations of the inventions.

The embodiment of the invention in which an exclusive property or privilege is claimed are defined as follows.

1. A method for adjusting the optical properties of an anti-reflective coating (ARC) layer comprising the steps of:
providing a preprocessed semiconductor substrate having a SiNₓ or a polysilicon layer on a top surface;
depositing a dielectric ARC layer on said SiNₓ or said polysilicon layer; and
annealing said dielectric ARC layer deposited on said semiconductor substrate at a temperature of at least 400° C. and in a gas comprising at least one element selected from the group consisting of N₂ and O₂.

2. A method for adjusting the optical properties of an anti-reflective coating layer according to claim 1 further comprising the step of depositing SiON or SiONH on said SiNₓ or said polysilicon layer.

3. A method for adjusting the optical properties of an anti-reflective coating layer according to claim 1 further comprising the step of depositing SiON on said SiNₓ or said polysilicon layer by a plasma enhanced chemical vapor deposition (PECVD) technique.

4. A method for adjusting the optical properties of an anti-reflective coating layer according to claim 1 further comprising the step of depositing SiON on said SiNₓ or said polysilicon layer by a plasma enhanced chemical vapor deposition (PECVD) technique to a thickness of at least 500 Å.

5. A method for adjusting the optical properties of an anti-reflective coating layer according to claim 1, wherein said gas used in said annealing process is O₂.

6. A method for adjusting the optical properties of an anti-reflective coating layer according to claim 1, wherein said gas used in said annealing process is N₂.

7. A method for adjusting the optical properties of an anti-reflective coating layer according to claim 1, wherein said gas used in said annealing process is a mixture of O₂ and N₂.

8. A method for adjusting the optical properties of an anti-reflective coating layer according to claim 1, wherein said dielectric anti-reflective coating layer is deposited of a material selected from the group consisting of SiO₂, SiON and SiONH.

9. A method for adjusting the optical properties of an anti-reflective coating layer according to claim 1 further comprising the step of annealing said dielectric anti-reflective coating layer at a temperature between about 400° C. and about 1,000° C.

10. A method for adjusting the optical properties of an anti-reflective coating layer according to claim 1 further comprising the step of annealing said dielectric anti-reflective coating layer for a time period between about 1 min. and about 30 min.

11. A method for adjusting the optical properties of an anti-reflective coating layer according to claim 1 further comprising the step of annealing said dielectric anti-reflective coating layer for a time period between about 1 min. and about 30 min.

12. A method for adjusting the optical properties of an anti-reflective coating layer according to claim 1 further comprising the step of adjusting said optical properties of the dielectric anti-reflective coating layer to a reflective index (n) between about 2.0 and about 2.5, and an extinction coefficient (k) between about 0.2 and about 0.8.

13. A method for adjusting the extinction coefficient (k) of a dielectric anti-reflective coating layer by the steps of:
providing a SiNₓ or polysilicon layer covered semiconductor substrate;
depositing a dielectric anti-reflective coating layer of a material selected from the group consisting of SiO₂, SiON and SiONH on top of said SiNₓ or said polysilicon layer; and
heating said semiconductor substrate to a temperature between about 400° C. and about 1,000° C. in an environment that comprises at least one of N₂ or O₂.

14. A method for adjusting the extinction coefficient (k) of a dielectric anti-reflective coating layer according to claim 13 further comprising the step of heating said semiconductor substrate for a length of time sufficient to vary the extinction coefficient of said dielectric anti-reflective coting layer by at least 10%.

15. A method for adjusting the extinction coefficient (k) of a dielectric anti-reflective coating layer according to claim 13 further comprising the step of heating said semiconductor substrate for a length of time between about 1 min. and about 30 min.

16. A method for adjusting the extinction coefficient (k) of a dielectric anti-reflective coating layer according to claim 13 further comprising the step of heating said semiconductor substrate for a length of time between about 3 min. and about 5 min.

17. A method for adjusting the extinction coefficient (k) of a dielectric anti-reflective coating layer according to claim 13 further comprising the step of heating said semiconductor substrate to a temperature of at least 600° C. in an environment of O₂.
